(19) United States
(12) Patent Application Publication
(10) Pub. No.: US 2026/0113875 A1
(43) Pub. Date: Apr. 23, 2026

(54) COOLING DISTRIBUTION UNIT WITH COOLED ELECTRICAL BOX

(71) Applicant: LTI Holdings, Inc., Pleasanton, CA (US)

(72) Inventors: Steven J. Medeiros, Loudon, NH (US); Jeffrey A. Henning, Exeter, NH (US); Peter D. Bennett, Hampton, NH (US)

(21) Appl. No.: 19/359,937

(22) Filed: Oct. 16, 2025

Related U.S. Application Data
(60) Provisional application No. 63/708,585, filed on Oct. 17, 2024.

(51) Int. Cl. H05K 7/20

(52) U.S. Cl. CPC H05K 7/20272; H05K 7/20254; H05K 7/20263; H05K 7/20281

(57) ABSTRACT

A cooling distribution unit includes a primary closed loop configured to circulate a first fluid to a cooling structure for removal of heat from the first fluid, a secondary closed loop configured to circulate a second fluid to an electrical component and pick up heat from the an electrical component, an electrical box containing an electronic device configured to control operation of the cooling distribution unit, and a heat exchanger coupled to the electrical box. The heat exchanger is coupled to the primary closed loop such that a portion of the first fluid circulates through the electrical box to maintain an operating temperature of the electrical box.

### CROSS-REFERENCE TO RELATED APPLICATIONS

This application claims priority to U.S. Provisional Application No. 63/708,585, filed Oct. 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU's) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a primary closed loop configured to circulate a first fluid to a cooling structure for removal of heat from the first fluid, a secondary closed loop configured to circulate a second fluid to an electrical component and pick up heat from the electrical component, an electrical box containing an electronic device configured to control operation of the cooling distribution unit, and a heat exchanger coupled to the electrical box. The heat exchanger is coupled to the primary closed loop such that a portion of the first fluid circulates through the electrical box to maintain an operating temperature of the electrical box.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a perspective view of the cooling distribution unit of FIG. 1, including an electrical box.

FIG. 6 is a perspective view of the electrical box of FIG. 5, connected to a primary closed loop shown schematically.

### DETAILED DESCRIPTION

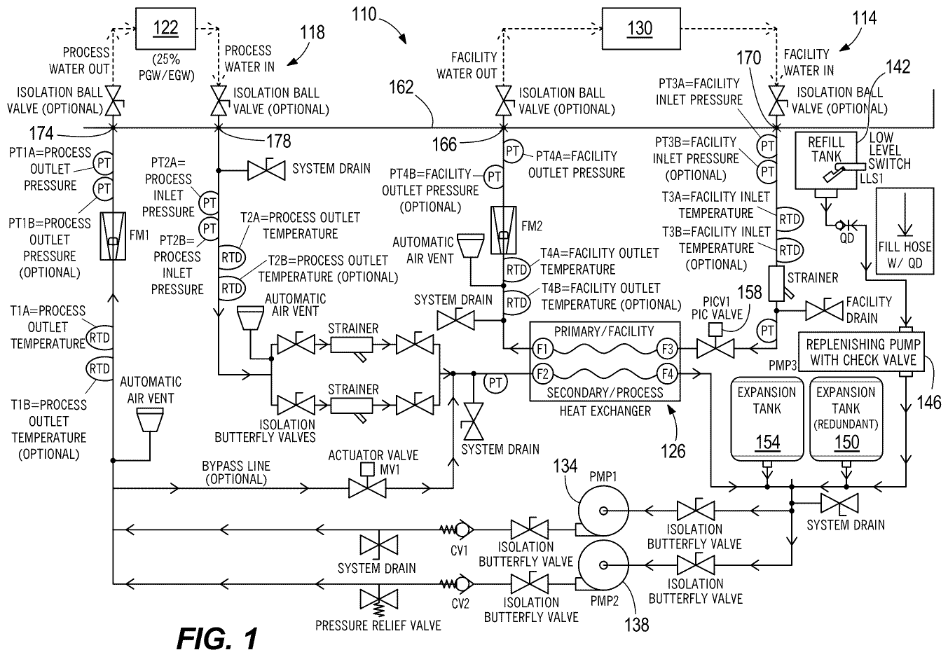

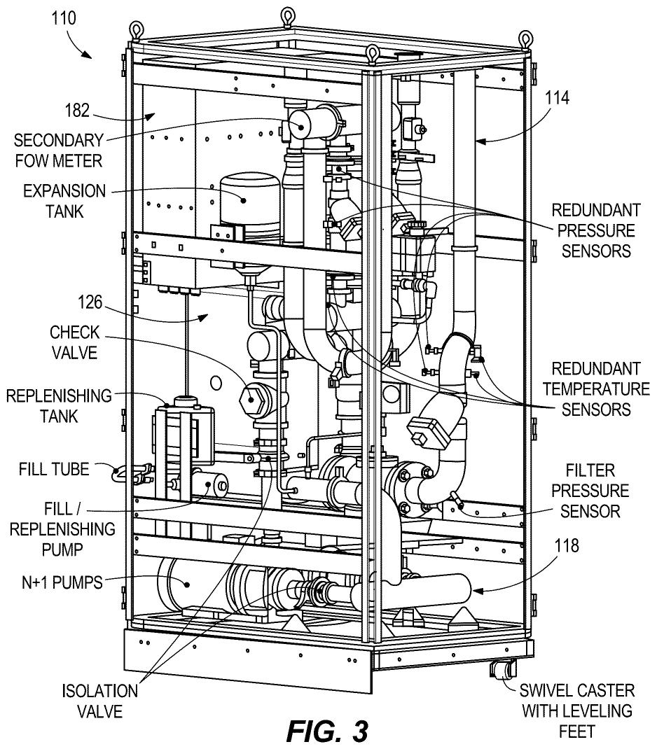

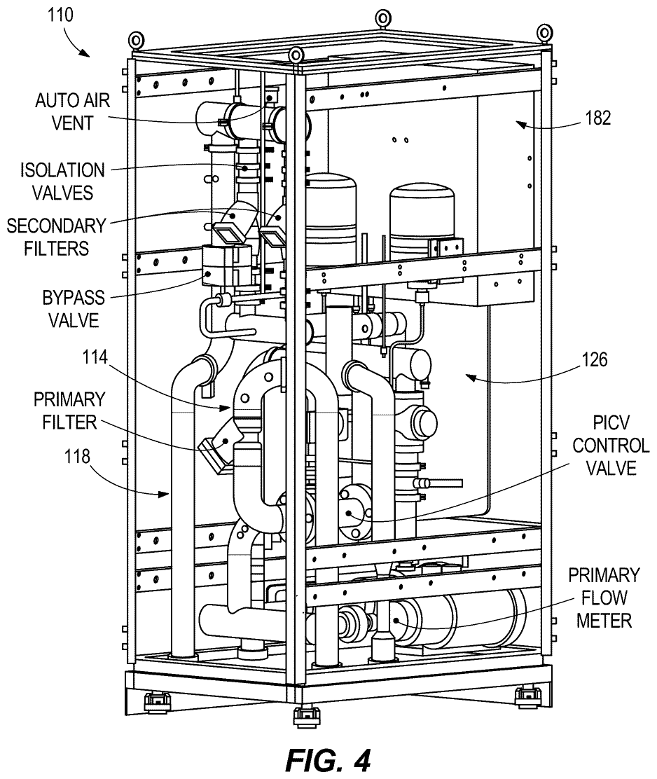

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

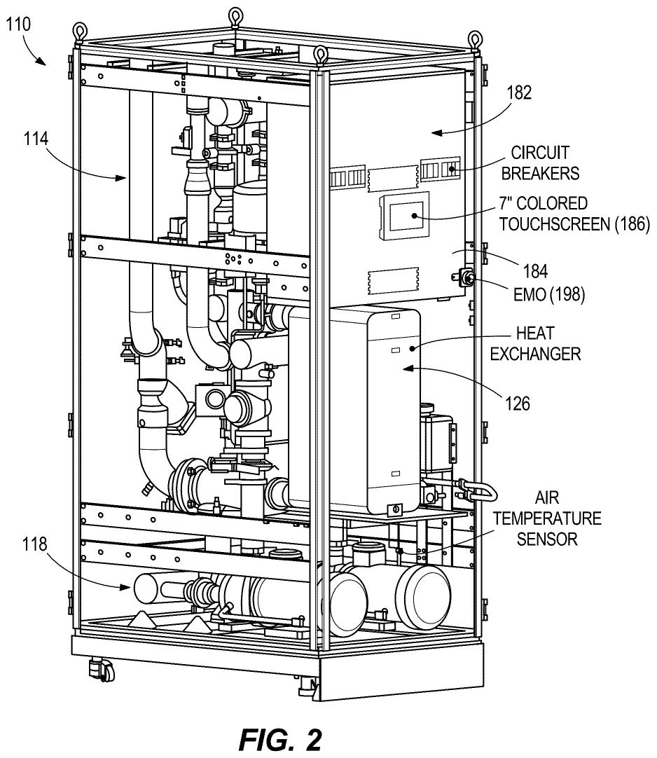

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. In some examples, at least a portion of the piping for the primary closed loop 114 and/or the secondary closed loop 118 is cylindrical in shape and/or has a circular cross-section. In some examples, at least a portion of the piping for the primary closed loop 114 and/or the secondary closed loop 118 has a linear section and/or a curved section. Other examples include other types of piping, including piping made of other materials (e.g., metal or non-metal), or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50 GPM, 100 GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

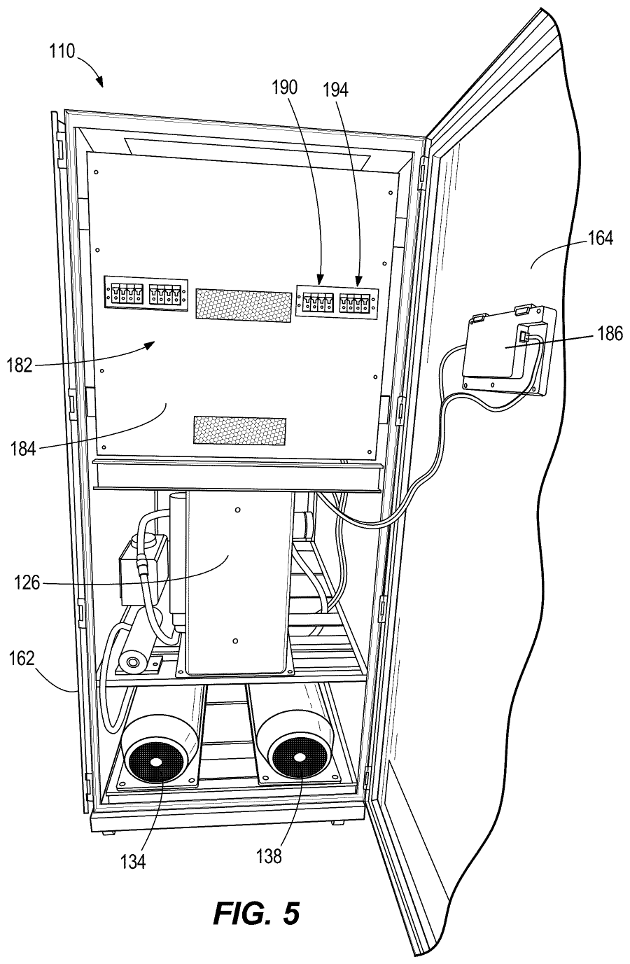

With continued reference to FIG. 1, in the illustrated example, the cooling distribution unit 110 includes a housing 162 (e.g., an outer housing; FIG. 5). The housing 162 may include a steel frame (e.g., with interconnected vertical and/or horizontal frame members), or may be another type of frame, or be formed from different materials. In some examples, the housing 162 includes one or more doors 164 (e.g., pivotally coupled or otherwise coupled to the frame as seen in FIG. 5). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

In the illustrated example, the cooling distribution unit 110 has an overall dimension of 31.5″ by 47.4″ by 84.5″, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550 KW (at 4° C. approach temperature difference) and 1100 KW (at 8° C. approach temperature difference). Other examples may include other values and ranges of values of cooling capacity, including a cooling capacity smaller or greater than that illustrated.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

With reference to FIGS. 2-4, the cooling distribution unit 110 includes an electrical box 182 (e.g., disposed on and/or within the housing 162 or located remotely from the housing 162). The electrical box 182, which may form part of and/or otherwise include or be considered a controller) contains one or more electronic devices configured to control and monitor the operation of the cooling distribution unit 110. For example, the electronic devices may be configured to monitor pressure, monitor temperature, and/or control a flow and pressure differential of the first fluid and/or the second fluid. The electrical box 12 may be rectangular in shape, square in shape, or have any other shape, and/or may be partially open, entirely enclosed, and/or have various other shapes, sizes, and configurations than that illustrated.

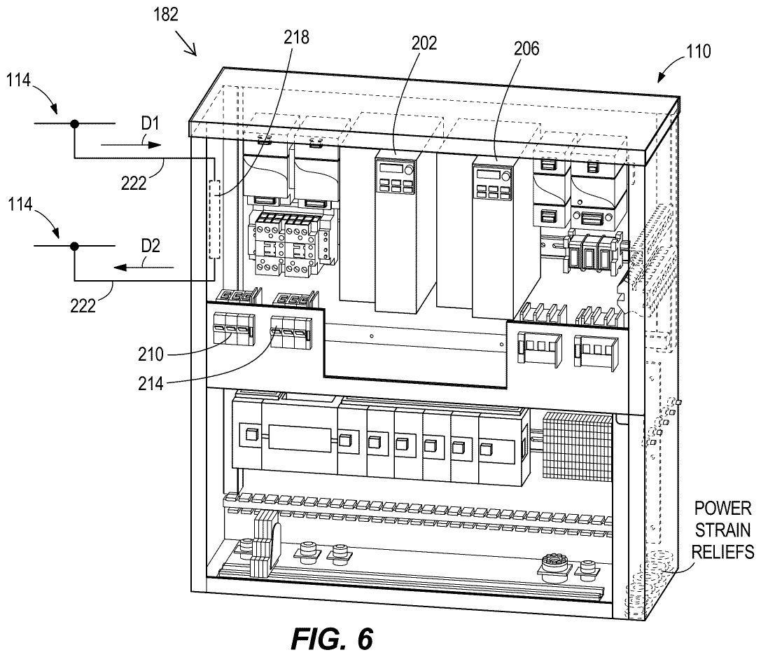

With reference to FIGS. 5 and 6, the electrical box 182 is formed as a metal enclosure. On a front surface 184 (or other surface or region), the electrical box 182 may include or be attached to a human machine interface (HMI) 186, a main power circuit breaker 190, an auxiliary power circuit breaker 194, and/or an emergency shutoff button 198 (FIG. 2). In some examples, and as seen in FIG. 5, the HMI 186 extends through the housing 162 and/or is coupled to the door 164 such that a user is able to operate the HMI 186 when the door 164 is shut to actuate the cooling distribution unit 110. In the illustrated example, the HMI 186 is a high-resolution color touch screen. The emergency shutoff button 198 may be actuated by the user to immediately stop operations of the cooling distribution unit 110.

With reference to FIG. 6, electronic devices such as a programmable logic controller (PLC; not shown), relays (not shown), a first variable frequency drive (VFD) 202 for the first pump 134, and/or a second variable frequency drive (VFD) 206 for the second pump 138, may be disposed within the electrical box 182. In some examples, the PLC is electrically connected to the HMI 186 and has several I/O modules. The first VFD 202 and the second VFD 206 are provided to control a speed of the first pump 134 and the second pump 138. Also, a first pump circuit breaker 210 and/or a second pump circuit breaker 214 may be provided within the electrical box 182. The first pump circuit breaker 210 is provided for the operation of the first VFD 202 and the first pump 134. The second pump circuit breaker 214 is provided for the operation of the second VFD 206. In some examples, the sensors are coupled (e.g., wired or wirelessly) to the electrical box 182. In other examples, the sensors are coupled (e.g., wired or wirelessly) to another device that receives signals regarding the pressure and temperature of the first fluid and/or the second fluid.

The cooling distribution unit 110 may be located within a setting (e.g., data center) that has an ambient temperature for example of 45 degrees Celsius or more. In such a warm setting, the cooling distribution unit 110 may also include a heat exchanger 218 (e.g., a liquid-to-liquid heat exchanger, a liquid-to-air heat exchanger, a fan-cooled heat exchanger, a cold plate heat exchanger, a finned heat exchanger, and/or other heat exchanger) coupled to (e.g., disposed on or within) the electrical box 182, and an electrical box line 222 extending from the piping of the primary closed loop 114 to circulate a portion of the first fluid through the electrical box 182. The electrical box line 222 is, for example, a pipe extending through the electrical box 182 to be connected to the heat exchanger 218. In some examples, the electrical box line 222 feeds a portion of the first fluid, that has passed through the cooling structure 130, into the electrical box 182 in a first direction D1. The portion of the first fluid is circulated through the electrical box 182 and the heat exchanger 218 for cooling the electronic devices. As such, the primary closed loop 114 and the heat exchanger 218 permit proper operation of the cooling distribution unit 110 in a setting having high ambient temperatures.

In some examples, the heat exchanger 218 is a liquid-to-air heat exchanger having one or more tubes connected to the electrical box line 222. The portion of the first fluid is circulated through the liquid-to-air heat exchanger such that the first fluid removes heat from the electrical box 182 by heat transfer between the portion of the first fluid and air within the electrical box 182. After removing heat from the electrical box 182, the portion of the first fluid is circulated back to the piping of the primary closed loop 114 in a second direction D2. The portion of the first fluid is then circulated through the cooling structure 130 so that the heat from the electrical box 182 is removed from the first fluid. In other examples, the heat exchanger 218 is a cold plate heat exchanger connected to the electrical box line 222. The primary closed loop 114 passes through the cold plate, so that the portion of the first fluid is circulated through the cold plate to thereby remove heat from the electrical box 182. In additional examples, one or more fans (not shown) may also be provided to supply cool air into the electrical box 182 for cooling the electronic devices.

Overall, the heat exchanger 218 is provided to actively cool the electrical box 182, and more specifically the electronic devices, during operation of the cooling distribution unit 110. As such, the heat exchanger 218 maintains a proper operating temperature of the electrical box 182. Also, utilizing the first fluid from the primary closed loop 114 to cool the electronic devices may eliminate the need for adding a separate cooling system that may otherwise increase cost and weight of the cooling distribution unit 110.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a primary closed loop configured to circulate a first fluid to a cooling structure for removal of heat from the first fluid;
a secondary closed loop configured to circulate a second fluid to an electrical component and pick up heat from the electrical component;
an electrical box containing an electronic device configured to control operation of the cooling distribution unit; and
a heat exchanger coupled to the electrical box, wherein the heat exchanger is coupled to the primary closed loop such that a portion of the first fluid circulates through the heat exchanger to maintain an operating temperature of the electrical box.

2. The cooling distribution unit of claim 1, wherein the primary closed loop extends through the electrical box to be connected to the heat exchanger and circulate the portion of the first fluid through the electrical box.

3. The cooling distribution unit of claim 1, wherein the heat exchanger is a liquid-to-air heat exchanger.

4. The cooling distribution unit of claim 1, wherein the heat exchanger is a cold plate heat exchanger.

5. The cooling distribution unit of claim 1, wherein the heat exchanger is disposed within the electrical box.

6. The cooling distribution unit of claim 1, wherein the electronic device includes at least one of a programmable logic controller, a relay, or a variable frequency drive.

7. The cooling distribution unit of claim 1, wherein the heat exchanger is a first heat exchanger, wherein the cooling distribution unit further includes a second heat exchanger through which the primary closed loop and the secondary closed loop extend for heat transfer between the first fluid and the second fluid.

8. The cooling distribution unit of claim 7, wherein the primary closed loop and the secondary closed loop each include a pump to respectively pump the first fluid through the primary closed loop and the second fluid through the secondary closed loop.

9. The cooling distribution unit of claim 7, wherein the second heat exchanger is a liquid-to-liquid heat exchanger.

10. The cooling distribution unit of claim 1, further comprising a first pump and a second pump, wherein the first pump and the second pump are redundant pumps, wherein the electrical box includes a first variable frequency drive for the first pump, and a second variable frequency drive for the second pump.

11. The cooling distribution unit of claim 10, wherein the electrical box further includes a first pump circuit breaker for operation of the first variable frequency drive and a second pump circuit breaker for operation of the second variable frequency drive.

12. The cooling distribution unit of claim 1, further comprising a human machine interface coupled to the electrical box.

13. The cooling distribution unit of claim 1, wherein the electrical box includes a front surface, wherein a main power circuit breaker is located along the front surface of the electrical box.

14. The cooling distribution unit of claim 13, further comprising an auxiliary power circuit breaker located along the front surface of the electrical box.

15. The cooling distribution unit of claim 1, further comprising an emergency shutoff button.

16. The cooling distribution unit of claim 1, further comprising a housing, wherein the electrical box is positioned within the housing.

17. The cooling distribution unit of claim 16, further comprising a door pivotally coupled to the housing.

18. The cooling distribution unit of claim 17, further comprising a human machine interface coupled to the door.

19. The cooling distribution unit of claim 1, further comprising a plurality of sensors configured to measure pressure and temperature within the cooling distribution unit, wherein each of the plurality of sensors is coupled to the electrical box.

20. The cooling distribution unit of claim 19, wherein at least one of the plurality of sensors is coupled wirelessly to the electrical box.
